(19) United States
(12) Patent Application Publication
(10) Pub. No.: US 2014/0064003 A1
(43) Pub. Date: Mar. 6, 2014

(54) FUSE CIRCUIT, OPERATING METHOD THEREOF, AND SEMICONDUCTOR MEMORY DEVICE INCLUDING THE FUSE CIRCUIT

(71) Applicant: SK HYNIX INC., Icheon-si (KR)

(72) Inventor: Kyeong-Pil KANG, Icheon-si (KR)

(73) Assignee: SK HYNIX INC., Icheon-si (KR)

(21) Appl. No.: 13/717,491

(22) Filed: Dec. 17, 2012

(30) Foreign Application Priority Data
Aug. 31, 2012 (KR) 10-2012-0096494

(51) Int. Cl. G11C 17/16; G11C 7/12

(52) U.S. Cl. CPC G11C 17/16; G11C 7/12
USPC 365/203; 365/225.7

(57) ABSTRACT

A semiconductor memory device includes a fuse unit including a fuse configured to be programmed with a repair target address, an enable unit configured to enable the fuse unit, an output unit configured to output a signal corresponding to whether the fuse unit is programmed or not, and a control unit configured to control a voltage difference between both ends of the fuse unit in response to a control signal.

### CROSS-REFERENCE TO RELATED APPLICATIONS

The present application claims priority of Korean Patent Application No. 10-2012-0096494, filed on Aug. 31, 2012, which is incorporated herein by reference in its entirety.

### BACKGROUND

1. Field

Exemplary embodiments of the present invention relate to a semiconductor device, and more particularly, to a semiconductor memory device including a repair fuse circuit for controlling a redundancy memory cell.

2. Description of the Related Art

In general, semiconductor memory devices including a double data rate synchronous dynamic random access memory (DDR SDRAM) device have numerous memory cells provided therein. With the development of processing technology, the number of memory cells included in a semiconductor memory device has further increased. When any of the memory cells has a defect, and is thus failed, the semiconductor memory device having the failed memory cell cannot perform a desired operation, and must be discarded. However, with the recent developments in processing technology, such a defect occurs only in a small number of memory cells. Accordingly, when a semiconductor memory device is discarded as a defective product because of a small number of defects, it is very inefficient in terms of product yield. Therefore, semiconductor memory devices include redundancy memory cells as well as normal memory cells to compensate for failed memory cell(s) and to overcome the inefficiency.

A redundancy memory cell substitutes for a memory cell in which a defect occurred (hereafter, referred to as a repair target memory cell). More specifically, when a repair target memory cell is to be accessed during a read or write operation, a corresponding redundancy memory cell is accessed instead of the repair target memory cell. That is, when an address corresponding to the repair target memory cell is inputted, the semiconductor memory device performs a repair operation for accessing the redundancy memory cell instead of the repair target memory cell. Through the repair operation, the semiconductor memory device may guarantee a normal operation despite the existence of a repair target memory cell.

The semiconductor memory device requires other circuits in addition to the redundancy memory cells, in order to perform the repair operation. One of the circuits is a repair fuse circuit. The repair fuse circuit serves to store an address corresponding to the repair target memory cell (hereafter, referred to as a repair target address). The repair target address is programmed into each of fuses provided in the repair fuse circuit. The semiconductor device performs the repair operation using the repair target address programmed in the repair fuse circuit.

Here, the programming of the repair fuse circuit may include a series of operations for storing predetermined address data in fuses of the repair fuse circuit. In general, the fuse programming method representatively includes a laser cutting method and an electrical cutting method. The laser cutting method cuts a fuse by blowing out the fuse according to the address data using a laser beam, and the electrical cutting method cuts a fuse by applying an over-current to the fuse according to the address data. The laser cutting method has an advantage in that it may be performed more simply than the electrical cutting method, but has a disadvantage in that it must be performed at the wafer level before the semiconductor device is packaged.

FIG. 1 is a circuit diagram of a conventional repair fuse circuit.

Referring to FIG. 1, the repair fuse circuit includes a plurality of fuses F having a repair target address programmed therein. The plurality of fuses F is coupled to a plurality of NMOS transistors to receive a plurality of mat select signals XMATYF<0:N>, respectively, where N is a natural number.

Hereafter, a circuit operation of the repair fuse circuit will be described.

First, in a pre-charging operation, a pre-charging control signal WLCBYF is in a logic low state, and thus a node A is pre-charged to a power supply voltage VDD. At this time, an output signal YRA is in a logic high state.

Then, in a normal operation, the pre-charging control signal WLCBYF moves to a logic high state, and the mat select signals XMATYF<0:N> are activated. A voltage level of the node A is determined according to whether a fuse F, which is coupled to an NMOS transistor receiving an activated mat select signal, is programmed or not, that is, whether the fuse F is cut or not. In other words, if the fuse F corresponding to the activated mat select signal is not cut, the node A changes from the pre-charged voltage VDD to a ground voltage VSS, and the output signal YRA changes from a logic high state to a logic low state. On the other hand, if the fuse F corresponding to the activated mat select signal is cut, the node A maintains the power supply voltage VDD as the pre-charged voltage, and the output signal YRA maintains the logic high state.

However, a fuse having the above-described configuration has a problem in that, for various reasons, the cut fuse is susceptible to being reconnected such that it acts as an uncut fuse. The reconnection of the fuse may be caused by ionization and reduction of copper (Cu) forming the fuse. In other words, according to a voltage applied to both ends of the cut fuse, ionization occurs at an anode (+) of the fuse, and reduction occurs at a cathode (−) of the fuse. Accordingly, Cu ions move from the anode to the cathode of the fuse. Due to such chemical reactions, Cu ions are adsorbed to the cathode (−). As a result, the ends of the cut fuse gradually reconnect to form an uncut fuse. Hereafter, such a defect is referred to as a fuse defect.

Recently, with the increase in importance of the redundancy memory cells, the importance of the repair fuse circuit related to the redundancy memory cells has also increased. In such a situation, the fuse defect may serve as a fatal error of the semiconductor memory device.

### SUMMARY

An embodiment of the present invention is directed to a semiconductor memory device capable of setting both ends of a fuse to substantially the same voltage level.

Another embodiment of the present invention is directed to a semiconductor memory device capable of performing an equalizing operation on both ends of a fuse in response to a pre-charging operation of a repair fuse circuit.

In accordance with an embodiment of the present invention, a semiconductor memory device includes: a fuse unit including a fuse into which a repair target address is programmed; an enable unit configured to enable the fuse unit; an output unit configured to output a signal corresponding to whether the fuse unit is cut or not; and an equalizing unit configured to equalize both ends of the fuse in response to an equalization control signal.

The semiconductor memory device may further include a pre-charging unit configured to pre-charge an input terminal of the output unit in response to a pre-charging control signal, and the equalization control signal may correspond to the pre-charging control signal.

In accordance with another embodiment of the present invention, an operating method of a semiconductor memory device includes: performing a programming operation on a fuse in response to predetermined data; outputting data programmed in the fuse; and equalizing both ends of the fuse in other periods excluding the outputting of the data.

The equalizing of both ends of the fuse may include electrically connecting both ends of the fuse.

In accordance with yet another embodiment of the present invention, an operating method of a semiconductor memory device includes: outputting data programmed in a fuse through a predetermined node; and pre-charging the predetermined node, wherein the pre-charging of the predetermined node includes equalizing both ends of the fuse.

The equalizing of both ends of the fuse may be disabled before the outputting of the data.

### BRIEF DESCRIPTION OF THE DRAWINGS

FIG. 1 is a circuit diagram of a conventional repair fuse circuit.

FIG. 2 illustrates a repair fuse circuit of a semiconductor memory device in accordance with an embodiment of the present invention.

FIG. 3 is a timing diagram for explaining an operation of the repair fuse circuit of FIG. 2

FIG. 4 is a circuit diagram of a repair fuse circuit of a semiconductor memory device in accordance with another embodiment of the present invention.

FIG. 5 is a timing diagram for explaining an operation of the repair fuse circuit of FIG. 4.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

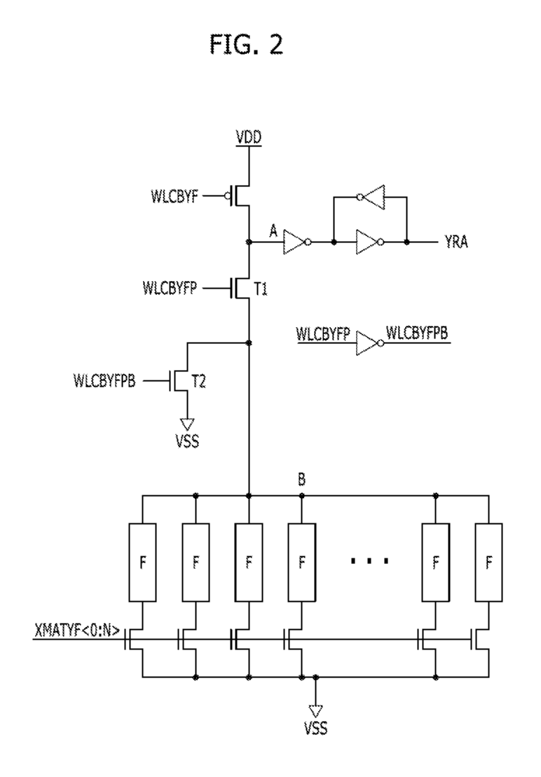

FIG. 2 illustrates a repair fuse circuit of a semiconductor memory device in accordance with an embodiment of the present invention.

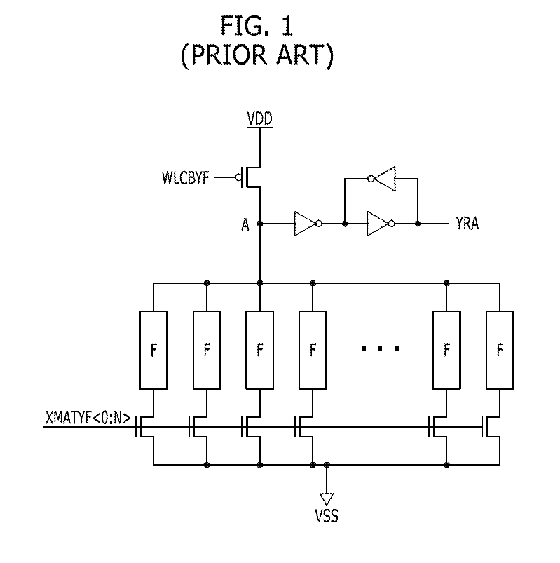

Referring to FIG. 2, the repair fuse circuit further includes a coupling unit and a control unit, the coupling unit including a first NMOS transistor T1 and the control unit including a second NMOS transistor T2, compared to the repair fuse circuit of FIG. 1. More specifically, the first NMOS transistor T1 is configured to control a coupling operation between nodes A and B in response to a coupling control signal, e.g., a first control signal WLCBYFP, and the second NMOS transistor T2 is configured to control a discharge operation for the node B in response to a second control signal WLCBYFPB.

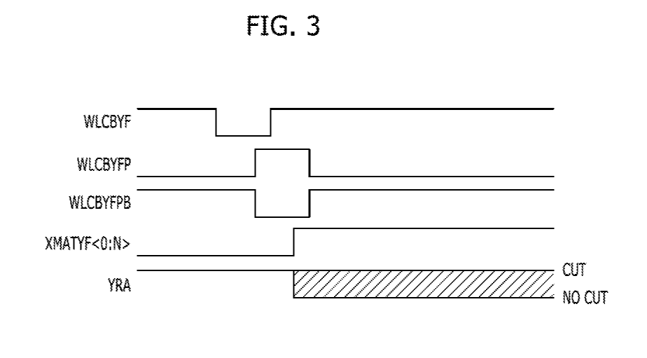

FIG. 3 is a timing diagram for explaining an operation of the repair fuse circuit of FIG. 2. Hereafter, referring to FIG. 3, the operation of the repair fuse circuit in FIG. 2 will be described.

First, in a pre-charging operation, a pre-charging control signal WLCBYF is enabled to a logic low level, and thus the node A is pre-charged to a power supply voltage VDD. At this time, the first control signal WLCBYFP has a logic low level to turn off the first NMOS transistor T1. Therefore, the nodes A and B are isolated from each other by the first NMOS transistor T1 that is turned off. On the other hand, the second control signal WLCBYFPB has a logic high level to turn on the second NMOS transistor T2. Therefore, a ground voltage VSS is applied to the node B, and thus the node B is discharged to the ground voltage VSS.

Meanwhile, before the pre-charging control signal WLCBYF transits from a logic low level to a logic high level, the first control signal WLCBYFP moves to a logic high level, and the second control signal WLCBYFPB moves to a logic low level. Therefore, the first NMOS transistor T1 is turned on to couple the nodes A and B, and the second NMOS transistor T2 is turned off to stop the discharge operation on the node B. Then, when the pre-charging control signal WLCBYF moves to a logic high level, the pre-charging operation on the node A is stopped.

In a normal operation, if any one of a plurality of mat select signals XMATYF<0:N> is activated to a logic high level to turn on a corresponding one of NMOS transistors coupled to and disposed between the plurality of fuses F and the ground voltage VSS, the voltage level of the node A is determined according to whether a selected fuse F coupled to the activated mat select signal is programmed or not. That is, the voltage level of the node A is determined based on whether the selected fuse F is cut or not. In other words, if the selected fuse F is not programmed (NO CUT), an output signal YRA moves to a logic low level, and if the selected fuse F is programmed (CUT), the output signal YRA maintains a logic high level.

Then, when the pre-charging operation is re-activated, the first control signal WLCBYFP moves to a logic low level, and the second control signal WLCBYFPB moves to a logic high level. Therefore, the first NMOS transistor T1 is turned off to isolate the node A from the node B, and the second transistor T2 is turned on to discharge the node B to the ground voltage VSS. Since both ends of the cut fuse F maintain the ground voltage VSS, a fuse defect does not occur.

In accordance with an embodiment as shown in FIG. 2, voltage levels of both ends of the cut fuse F may be controlled to prevent a fuse defect from occurring in the cut fuse F. In order to implement the repair fuse circuit in FIG. 2, in a preferred embodiment, the repair fuse circuit further includes a control signal generation block for generating the first and second control signals WLCBYFP and WLCBYFPB. Moreover, the first and second control signals WLCBYFP and WLCBYFPB should be provided to secure a sufficient margin between the pre-charging control signal WLCBYF and the plurality of mat select signals XMATYF<0:N>.

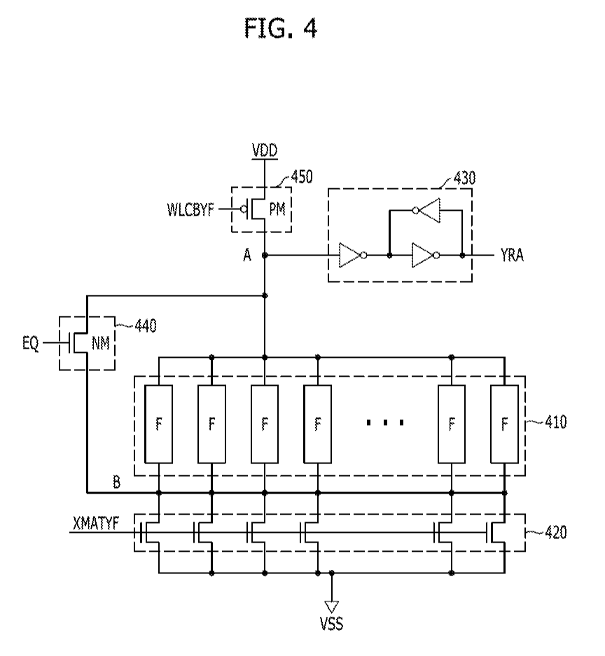

FIG. 4 is a circuit diagram of a repair fuse circuit of a semiconductor memory device in accordance with another embodiment of the present invention.

Referring to FIG. 4, the repair fuse circuit includes a fuse unit 410, an enable unit 420, an output unit 430, an equalizing unit 440, and a pre-charging unit 450.

The fuse unit 410 includes a plurality of fuses F. Here, a repair target address is programmed into each of the fuses F. The enable unit 420 includes a plurality of transistors and is configured to activate the plurality of fuses F in response to respective mat select signals XMATYF<0:N>. The output unit 430 is coupled to a node A coupled to the fuse unit 410 and configured to generate an output signal YRA in response to whether the plurality of fuses F are programmed or not. The equalizing unit 440 as a control unit is configured to equalize both ends of the plurality of fuses F in response to an equalizing signal EQ. The pre-charging unit 450 is configured to pre-charge the node A in response to a pre-charging control signal WLCBYF.

FIG. 4 representatively illustrates one equalizing unit 440 corresponding to the plurality of fuses F. The equalizing unit 440 includes an NMOS transistor NM configured to form a source-drain path between both ends of the fuses F (between the nodes A and B) and receive the equalization control signal EQ through a gate thereof. The pre-charging unit 450 includes a PMOS transistor PM configured to form a source-drain path between a power supply voltage terminal VDD and the node A, and receive the pre-charging control signal WLCBYF through a gate thereof.

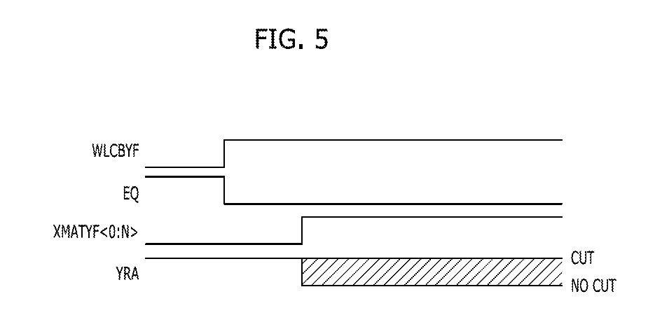

FIG. 5 is a timing diagram for explaining an operation of the repair fuse circuit of FIG. 4. Hereafter, referring to FIG. 5, the operation of the repair fuse circuit of FIG. 4 will be described.

First, in a pre-charging operation, the pre-charging control signal WLCBYF has a logic low level, and the node A is pre-charged to the power supply voltage VDD. When the equalization control signal EQ has a logic high level, the NMOS transistor NM is turned on to electrically couple the nodes A and B. That is, the nodes A and B are equalized to maintain the same voltage level. Then, if the pre-charging control signal WLCBYF moves to a logic high level, the PMOS transistor PM is turned off to stop the pre-charging operation.

In accordance with an embodiment of the present invention, a change in the equalization control signal EQ corresponds to a change in the pre-charging control signal WLCBYF. That is, the equalization control signal EQ may be obtained by inverting the pre-charging control signal WLCBYF. Thus, the equalization control signal EQ may be deactivated to a logic low level if the pre-charging control signal WLCBYF moves to the logic high level before any one of the plurality of mat select signals XMATYF<0:N> is activated to a logic high level to turn on a corresponding one of the transistors in the enable unit 420.

In a normal operation, i.e., if any one of the plurality of mat select signals XMATYF<0:N> is activated to a logic high level to turn on a corresponding one of transistors in the enable unit 420, the voltage level of the node A is determined according to whether a selected fuse F coupled to the activated mat select signal is programmed or not. That is, the voltage level of the node A is determined based on whether or not the selected fuse F is cut. In other words, if the selected fuse F is not programmed (NO CUT), the output signal YRA moves to a logic low level, and if the selected fuse F is cut (CUT), the output signal YRA maintains a logic high level.

A semiconductor memory device in accordance with an embodiment of the present invention equalizes both ends of the fuse F, thereby suppressing the occurrence of a fuse defect in the cut fuse. Furthermore, the above-described circuit operation may be performed when the NMOS transistor NM is turned on or off in response to the equalization control signal EQ. The equalization control signal EQ is generated to correspond to the pre-charging control signal WLCBYF. For example, in an embodiment, a simple inverter circuit may be used to generate the equalization control signal EQ. Therefore, it is possible to reduce a circuit area when designing the circuit for generating the equalization control signal EQ.

In accordance with an embodiment of the present invention, a semiconductor memory device may maintain substantially the same voltage level at both ends of a fuse. As a result, defects in the fuse can be prevented, and a malfunction caused by a defective fuse can be reduced. Furthermore, since a stable repair operation of the repair fuse circuit may be guaranteed, it is possible to increase the reliability of the semiconductor memory device.

In the embodiments of the present invention described above, the fuse used in the repair fuse circuit was taken as an example, but the present invention may also be applied to various fuses used in semiconductor memory devices. Furthermore, a fuse having a dynamic structure was taken as an example, but the present invention may be applied to a fuse having a static structure.

Furthermore, the positions and types of the logic gates and transistors in the above-described embodiments of the present invention may be differently set depending on the polarities of input signals.

While the present invention has been described with respect to specific embodiments, it will be apparent to those skilled in the art that various changes and modifications may be made without departing from the spirit and scope of the invention as defined in the following claims.

What is claimed is:

1. A semiconductor memory device, comprising:
a fuse unit comprising a fuse configured to be programmed with a repair target address;
an enable unit configured to activate the fuse unit;
an output unit configured to output a signal corresponding to whether the fuse unit is programmed or not; and
a control unit configured to control a voltage difference between both ends of the fuse in response to a control signal.

2. The semiconductor memory device of claim 1, wherein the control unit is configured to equalize voltage levels at the both ends of the fuse in response to the control signal, and
wherein the control signal is an equalization control signal.

3. The semiconductor memory device of claim 2, wherein the control unit is configured to electrically couple the both ends of the fuse in response to the equalization control signal.

4. The semiconductor memory device of claim 3, wherein the control unit comprises a transistor configured to form a path between the both ends of the fuse and receive the equalization control signal through a gate.

5. The semiconductor memory device of claim 1, further comprising a pre-charging unit configured to pre-charge an input terminal of the output unit in response to a pre-charging control signal.

6. The semiconductor memory device of claim 2, wherein the equalization control signal corresponds to a pre-charging control signal for pre-charging an input terminal of the output unit.

7. The semiconductor memory device of claim 1, wherein the fuse unit has a dynamic structure or a static structure.

8. The semiconductor memory device of claim 1, wherein the enable unit is configured to activate the fuse unit in response to a mat select signal corresponding to an address, and
wherein the control signal is deactivated before the mat select signal is activated.

9. The semiconductor memory device of claim 1, wherein a number of equalizing units corresponds to a number of fuse units.

10. The semiconductor memory device of claim 1, further comprising a coupling unit configured to couple or decouple the fuse unit and the output unit in response to a coupling control signal.

11. The semiconductor memory device of claim 10, wherein the control unit comprises a transistor coupled to and disposed between a ground voltage terminal and a connection node of the coupling unit and the fuse unit, the transistor including a gate to receive the control signal.

12. The semiconductor memory device of claim 1, wherein the control unit is deactivated before the fuse circuit is activated.

13. An operating method of a fuse circuit, the operating method comprising:
outputting data programmed in a fuse unit through a predetermined node; and
pre-charging the predetermined node to have a preset voltage,
wherein the pre-charging of the predetermined node comprises equalizing both ends of the fuse unit.

14. The operating method of claim 13, wherein the equalizing of the both ends of the fuse is disabled before the outputting of the data.

15. The operating method of claim 13, wherein the equalizing of the both ends of the fuse unit is performed in other periods than a period in which the outputting of the data is performed.

16. The operating method of claim 13, wherein the equalizing of the both ends of the fuse unit comprises electrically coupling the both ends of the fuse unit.

17. A fuse circuit, comprising:
a fuse unit comprising a fuse configured to be programmed with predetermined data;
an enable unit configured to activate the fuse unit;
an output unit configured to output a signal corresponding to whether the fuse unit is programmed or not; and
an equalizing unit configured to equalize voltage levels at both ends of the fuse in response to an equalization control signal.

18. The fuse circuit of claim 17, wherein the equalizing unit is deactivated before the fuse unit is activated.

19. The fuse circuit of claim 17, wherein the equalizing unit is configured to electrically couple the both ends of the fuse.

20. The fuse circuit of claim 17, further comprising a pre-charging unit configured to pre-charge an input terminal of the output unit in response to a pre-charging control signal, wherein the equalization control signal corresponds to the pre-charging control signal.
